(19) United States
(12) Patent Application Publication
(10) Pub. No.: US 2018/0229343 A1
(43) Pub. Date: Aug. 16, 2018

(54) CHEMICAL MECHANICAL POLISHING DEVICE

(71) Applicant: SAMSUNG ELECTRONICS CO., LTD., Suwon-si (KR)

(72) Inventors: Ho-joong KIM, Yongin-si (KR); Jun-yong KIM, Yongin-si (KR); Tae-sung KIM, Seoul (KR); Seok-jun HONG, Siheung-si (KR)

(73) Assignee: Research & Business Foundation SUNGKYUNKWAN UNIVER SITY, Suwon-si (KR)

(21) Appl. No.: 15/679,355

(22) Filed: Aug. 17, 2017

(30) Foreign Application Priority Data
Feb. 15, 2017 (KR) 10-2017-0020716

(51) Int. Cl. B24B 37/005; B24B 53/017; G01B 21/30; H01L 21/67; H01L 21/687

(52) U.S. Cl. CPC B24B 37/005; B24B 53/017; G01B 21/30; H01L 21/30625; H01L 21/68714; H01L 21/67248; H01L 21/67253

(57) ABSTRACT

A chemical mechanical polishing (CMP) device includes a rotatable CMP pad located on a polishing platen, a rotatable wafer carrier located on an upper portion of the CMP pad and including a wafer, and a surface-roughness measuring device which is located apart from a surface of the CMP pad in a vertical direction and measures surface roughness of the CMP pad, wherein the surface-roughness measuring device includes a sensor array having a plurality of sensors, and the sensor array is horizontally movable over the upper portion of the CMP pad.

### CROSS-REFERENCE TO RELATED APPLICATION

This application claims the benefit of Korean Patent Application No. 10-2017-0020716, filed on Feb. 15, 2017, in the Korean Intellectual Property Office, the disclosure of which is incorporated herein in its entirety by reference.

### BACKGROUND

Embodiments relate to a chemical mechanical polishing (CMP) device, and more particularly, to a CMP device capable of improving reliability of wafer planarization.

A chemical mechanical polishing (CMP) process using a CMP device may be used for planarization of wafers when manufacturing semiconductor devices. When the CMP process is performed, polishing precision of wafers is lowered due to high integration of semiconductor devices and an enlargement of diameters of the wafers, and thus, reliability of wafer planarization may be lowered.

### SUMMARY

Embodiments provide a chemical mechanical polishing (CMP) device capable of improving reliability of wafer planarization by improving polishing precision of wafers.

According to an aspect of embodiments, there is provided a CMP device including a rotatable CMP pad located on a polishing platen, a rotatable wafer carrier located on an upper portion of the CMP pad and including a wafer, and a surface-roughness measuring device which is located apart from a surface of the CMP pad in a vertical direction and measures surface roughness of the CMP pad, wherein the surface-roughness measuring device includes a sensor array having a plurality of sensors, and the sensor array is horizontally movable over the upper portion of the CMP pad.

According to another aspect of embodiments, there is provided a CMP device including a rotatable CMP pad located on a polishing platen, a rotatable wafer carrier including a wafer. wherein the wafer is polished in contact with the CMP pad, a surface-roughness measuring which is located apart from a surface of the CMP pad in a vertical direction and measures surface roughness of the CMP pad, and a controller configured to control the wafer carrier and the surface-roughness measuring device, wherein the surface-roughness measuring device includes a sensor array having a plurality of sensors, wherein the sensor array is horizontally movable over upper portion of the CMP pad, and the controller is configured to control polishing conditions of the wafer mounted on the wafer carrier in real time according to the surface roughness of the pad measured by the surface-roughness measuring device.

### BRIEF DESCRIPTION OF THE DRAWINGS

Example embodiments will be more clearly understood from the following detailed description taken in conjunction with the accompanying drawings, in which:

FIG. 1 is a perspective view of a chemical mechanical polishing (CMP) device according to an example embodiment;

FIG. 2 is a side view of the CMP device of FIG. 1;

FIG. 3 is a side view of the CMP device of FIG. 1;

FIG. 4 is a plan view of a partitioned CMP pad of the CMP device of FIG. 1;

FIGS. 5 and 6 are a schematic view and block diagrams of components of a CMP device and a control relationship of the components, according to an example embodiment, respectively;

FIGS. 7 and 8 are cross-sectional views for explaining a surface state of a CMP pad of a CMP device, according to an embodiment;

FIG. 9 is a graph of surface roughness of a CMP pad of a CMP device according to time of use, according to an embodiment;

FIGS. 10 and 11 are respectively a diagram and a graph for explaining a method of measuring surface roughness of a CMP pad of a CMP device, according to an example embodiment; and

FIG. 12 is a flowchart of a CMP method of a CMP device according to an example embodiment.

### DETAILED DESCRIPTION OF THE EMBODIMENTS

Reference will now be made in detail to example embodiments, examples of which are illustrated in the accompanying drawings. The example embodiments may be constituted by combining two or more of the example embodiments. Therefore, embodiments not limited to just one example embodiment.

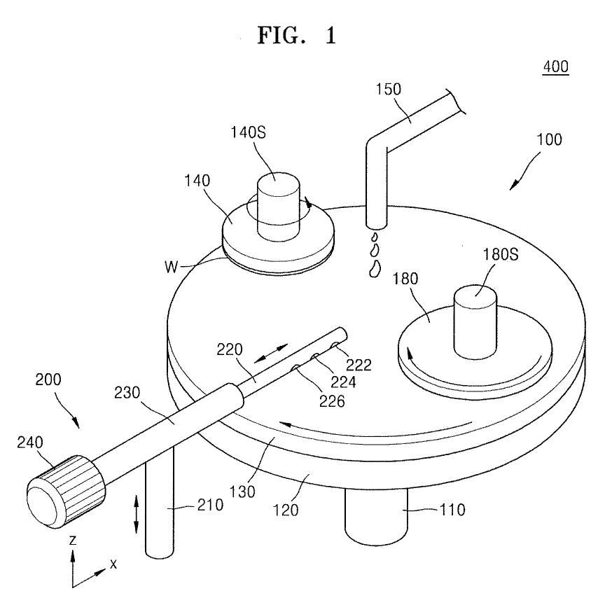

FIG. 1 is a perspective view of a chemical mechanical polishing (CMP) device 400 according to an example embodiment.

In more detail, the CMP device 400 may include a polishing device 100 (polishing unit) for polishing a wafer W by using a CMP pad 130, and a surface-roughness measuring device 200 for measuring surface roughness of the CMP pad 130.

The polishing device 100 constituting the CMP device 400 may include a polishing platen 120 mounted on a platen central axis 110 and the CMP pad 130 mounted on the polishing platen 120. The polishing platen 120 may be a rotary table formed in a disk shape and capable of rotating in a predetermined direction, for example, a clockwise direction. The CMP pad 130 may be a hard polyurethane pad.

The polishing device 100 constituting the CMP device 400 may include a wafer carrier 140 facing the CMP pad 130, installed under a carrier central axis 140S at a position eccentric from a center of the CMP pad 130, and rotatable in a predetermined direction, i.e., in a counter-clockwise direction by the carrier central axis 140S.

The wafer carrier 140 may install the wafer W that has a disk shape of a smaller diameter than the CMP pad 130. The wafer W installed by the wafer carrier 140 rotates while contacting the CMP pad 130 and a wafer planarization process may proceed through a CMP process using a slurry supplied from a slurry supply nozzle 150.

In one example embodiment, a rotation direction of the CMP pad 130 rotated by the polishing platen 120 may be different from a rotation direction of the wafer W rotated by the carrier central axis 140S.

The polishing device 100 constituting the CMP device 400 may include a CMP pad conditioner 180 facing the CMP pad 130, installed under a conditioner central axis 180S at a position eccentric from a center of the CMP pad 130, and rotatable in a predetermined direction, i.e., in a clockwise direction by the conditioner central axis 180S.

The CMP pad conditioner 180 may be a device for conditioning a surface of the CMP pad 130. The CMP pad conditioner 180 may polish a surface of the CMP pad 130 to maintain surface roughness of the CMP pad 130 in an optimal state.

The CMP pad conditioner 180 may recover or maintain the surface roughness of the CMP pad 130 by polishing the wafer W with the wafer carrier 140 or, when the polishing of the wafer W has stopped, by polishing the CMP pad 130.

The CMP pad conditioner 180 may be formed by abrasive particles, for example, artificial diamond particles, being evenly adhered to a circular disk made of metal through a nickel (Ni) bonding layer. In one example embodiment, a rotation direction of the wafer W rotated by the carrier central axis 140S may be different from a rotation direction of the CMP pad conditioner 180 rotated by the conditioner central axis 180S.

The CMP device 400 may include the surface-roughness measuring device 200 capable of measuring surface roughness of the CMP pad 130. Even if the CMP device 400 polishes the CMP pad 130 with the CMP pad conditioner 180, polishing precision and polishing efficiency of the wafer W may be lowered if chemical mechanical polishing is repeatedly continued.

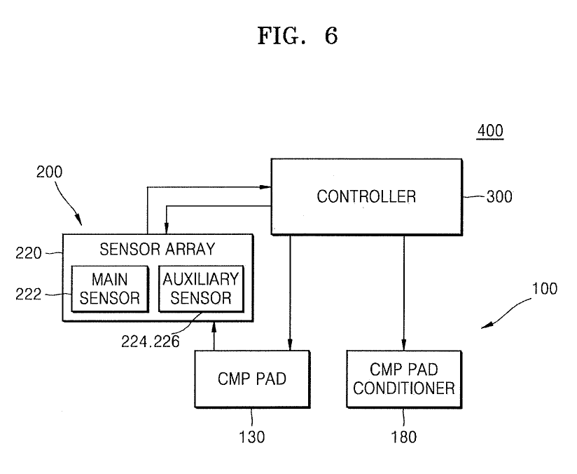

Accordingly, the CMP device 400 may include the surface-roughness measuring device 200 capable of accurately measuring surface roughness of the CMP pad 130 and improving polishing precision and polishing efficiency of the wafer W. The surface-roughness measuring device 200 may precisely measure surface roughness of the CMP pad 130 in real time and feed back a measuring result to a polishing device 100 through a controller 300 (refer to. e.g., FIGS. 5 and 6) to perform a CMP process while changing process conditions.

The surface-roughness measuring device 200 may include a vertical support 210 that is movable in a vertical direction (e.g., the Z-direction) and a horizontal support 230 that is on the vertical support 210 and extends in a horizontal direction (e.g., the X-direction) from the vertical support 210.

The surface-roughness measuring device 200 may include a sensor array 220 that is installed at one end of the horizontal support 230, spaced apart from an upper portion of the CMP pad 130 in the vertical direction (the Z-direction), and movable in the horizontal direction (the X-direction) by a motor 240.

In other words, the motor 240 is mechanically connected to the sensor array 220. When the motor 240 rotates, the sensor array 220 may be moved into the horizontal support 230 or extended over the CMP pad 130 to move in the horizontal direction (the X-direction).

The sensor array 220 may include a plurality of sensors 222, 224, and 226. The sensor array 220 may be a non-contact sensor array that does not contact the CMP pad 130. The sensor array 220 may include a main sensor 222 and auxiliary sensors 224 and 226.

The main sensor 222 may be a sensor capable of measuring surface roughness of the CMP pad 130. The auxiliary sensors 224 and 226 may assist the main sensor 222 to improve accuracy of the surface-roughness measurement of the CMP pad 130.

The auxiliary sensors 224 and 226 may be classified as a first auxiliary sensor 224 and a second auxiliary sensor 226. Although the sensor array 220 is described as including two auxiliary sensors 224 and 226, the sensor array 220 may include three or more auxiliary sensors in an embodiment.

The main sensor 222 may be an optical sensor capable of measuring surface roughness or a change in surface roughness of the CMP pad 130. The main sensor 222. i.e., the optical sensor 222, may be a sensor that irradiates light to a surface of the CMP pad 130 and then detects light reflected by the CMP pad 130 so as to output the reflected light as an electrical signal. The electrical signal output from the main sensor 222, i.e., the optical sensor 222. based on the reflected light may be analyzed by the controller 300 (refer to e.g., FIGS. 5 and 6) to measure surface roughness or a change in surface roughness of the CMP pad 130. as described later below.

The first auxiliary sensor 224 may be a temperature sensor capable of assisting the main sensor 222 in measuring surface roughness or a change in surface roughness of the CMP pad 130. The temperature sensor may measure a surface temperature of the CMP pad 130 and output the surface temperature as an electrical signal.

For example, the temperature sensor constituting the first auxiliary sensor 224 may measure a change in surface temperature that may occur due to a change in surface roughness of the CMP pad 130 as a CMP process proceeds.

The electrical signal output from the first auxiliary sensor 224 based on the change in the surface temperature of the CMP pad 130 may be analyzed by the controller 300 (refer to e.g., FIGS. 5 and 6) to measure surface roughness or a change in surface roughness of the CMP pad 130, as described later below.

The second auxiliary sensor 226 may be a microphone sensor capable of assisting the main sensor 222 in measuring surface roughness or a change in surface roughness of the CMP pad 130. The microphone sensor may be an acoustic emission (AE) sensor. The AE sensor may be a converter that receives an AE wave and converts the AE wave into an acoustic emission signal. The microphone sensor may be a sensor that measures sound emitted from the CMP pad 130 as a CMP process proceeds and emits an electrical signal.

For example, an AE sensor constituting the second auxiliary sensor 226 measures a change in sound emitted from the CMP pad 130 that may occur due to a change in surface roughness of the CMP pad 130 as a CMP process proceeds, and output an electrical signal.

The electrical signal output from the second auxiliary sensor 226 based on the change in the sound of the CMP pad 130 may be analyzed by the controller 300 (refer to e.g., FIGS. 5 and 6) to measure surface roughness or a change in surface roughness of the CMP pad 130, as described later below.

The CMP device 400 may comprehensively analyze electrical signals detected from the main sensor 222 and the auxiliary sensors 224 and 226 constituting the sensor array 220 to measure surface roughness of the CMP pad 130. In addition, the CMP device 400 may perform a CMP process while feeding back the measured surface roughness of the CMP pad 130 to the polishing device 100 to change process conditions in real time.

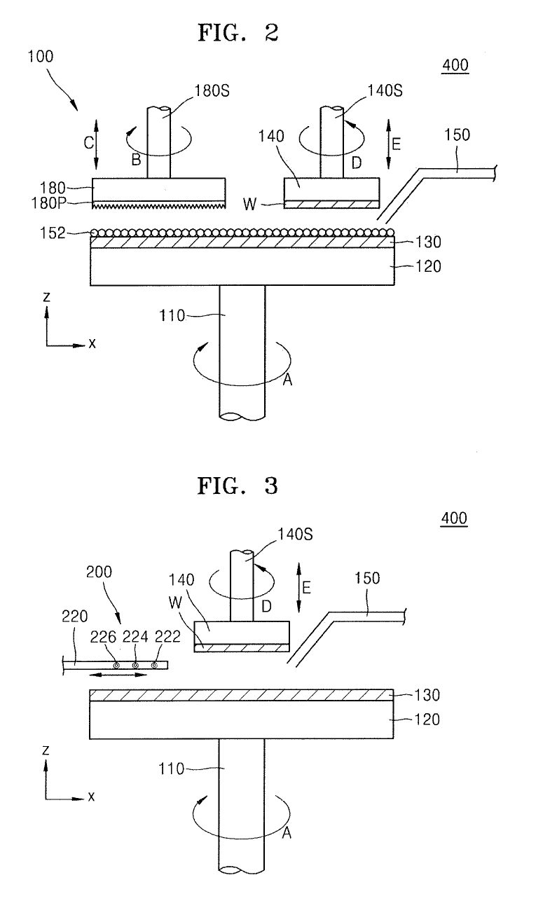

FIG. 2 is a side view of the CMP device 400 of FIG. 1 according to an embodiment.

The CMP device 400 shown in FIG. 2 may be provided to explain the polishing device 100 in which the wafer W is polished mainly by using the CMP pad 130.

The polishing device 100 includes the CMP pad 130 located on the polishing platen 120 mounted on the platen central axis 110 rotatable in direction A, i.e., in a clockwise direction. A polishing slurry (or abrasive grains) 152 supplied to the slurry supply nozzle 150 may be located on the CMP pad 130.

The wafer carrier 140 may be installed under the carrier central axis 140S rotatable in direction D, i.e., in a counter-clockwise direction, and the wafer W may be installed under the wafer carrier 140. The wafer W installed under the wafer carrier 140 is rotated in direction D and pressure is applied thereto in direction E so that it contacts the CMP pad 130 and so that a wafer planarization process may proceed. During the wafer planarization process, the platen central axis 110 may or may not rotate in direction A.

Referring to FIG. 2, the CMP pad conditioner 180 is installed under the conditioner central axis 180S rotatable in direction B. Abrasive particles 180P are formed on one surface of the CMP pad conditioner 180. The CMP pad conditioner 180 is rotated in direction B, i.e., a clockwise direction, and pressure is applied thereto in direction C so that the abrasive particles 180P contact the CMP pad 130 to polish a surface of the CMP pad 130 and maintain surface roughness of the CMP pad 130 in an optimal state.

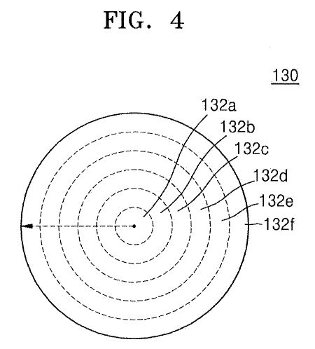

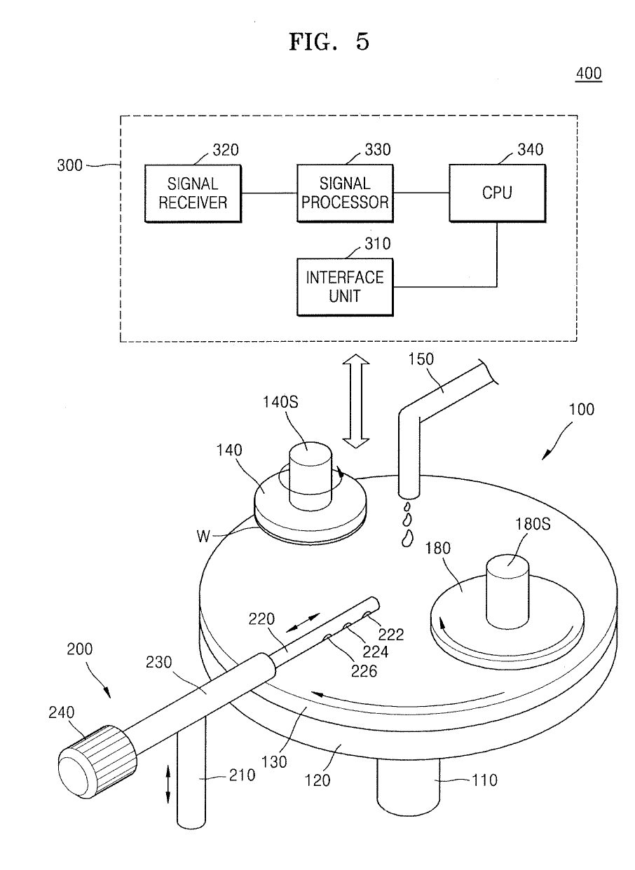

FIG. 3 is a side view of the CMP device 400 of FIG. 1, and FIG. 4 is a plan view of a partitioned CMP pad of the CMP device 400 of FIG. 1.

The side view of the CMP device 400 shown in FIG. 3 may be provided to explain the surface-roughness measuring device 200 that measures surface roughness of the CMP pad 130.

The surface-roughness measuring device 200 capable of measuring surface roughness of the CMP pad 130 may be provided over the CMP pad 130 in addition to the wafer carrier 140. surface-roughness measuring device 200 may be installed apart from one side of the CMP pad in a vertical direction. The surface-roughness measuring device 200 may include the sensor array 220 which is horizontally movable over an upper portion of the CMP pad 130. The sensor array 220 may include the main sensor 222 and the auxiliary sensors 224 and 226 to measure surface roughness of the CMP pad 130.

Referring to FIG. 4, the CMP pad 130 may be divided into a plurality of partitioned areas 132a to 132f having different diameters in a direction from a center to a contour. In FIG. 4, the CMP pad 130 is divided into six partitioned areas 132a to 132f for convenience, but the CMP pad 130 may be divided into more partitioned areas. The sensor array 220 is horizontally movable over an upper portion of the CMP pad 130, and the CMP pad 130 is rotated by the platen central axis 110. Thus, the sensor array 220 may measure surface roughness of all areas of the CMP [symbol] 6 are a schematic view and block diagrams of components of a CMP device and a control relationship of the components, according to an example embodiment, respectively.

Compared to FIG. 1, the CMP device 400 shown in FIG. 5 additionally includes the controller 300 for controlling the polishing device 100 and the surface-roughness measuring device 200 in addition to FIG. 1.

FIG. 6 is a block diagram for explaining a control relationship between the polishing device 100 including the CMP pad 130 and the CMP pad conditioner 180, the surface-roughness measuring device 200, and the controller 300.

The CMP device 400 may include the polishing device 100 that polishes the wafer W using the CMP pad 130 and the surface-roughness measuring device 200 that measures surface roughness of the CMP pad 130. The CMP device 400 may include the polishing device 100 including the CMP pad 130 and the CMP pad conditioner 180 and the controller 300 for controlling the surface-roughness measuring device 200.

Electrical signals output from the sensors 222, 224 and 226 of the sensor array 220 constituting the surface-roughness measuring device 200 based on surface roughness or a change in surface roughness of the CMP pad 130 may be received by a signal receiver 320 of the 300. The electrical signals received by the signal receiver 320 may be comprehensively analyzed and processed by a signal processor 330 so that surface roughness of the CMP pad 130 may be input to a central processing unit (CPU) (or a microprocessor) 340.

The signal processor 330 may comprehensively analyze intensity and the amount of reflected light output from the main sensor 222, and vibration frequencies and temperatures output from the auxiliary sensors 224 and 226 to obtain surface roughness of the CMP pad 130.

The signal processor 330 may include a logic circuit for selecting an optimal position for measuring surface roughness of the CMP pad 130, a logic circuit for selecting an optimum wavelength for measuring surface roughness of the CMP pad 130, a logic circuit for compensating for intensity of a light spectrum and a vibration frequency according to temperature of the CMP pad 130, and the like.

The signal processor 330 may include a logic circuit for compensating for a difference between surface roughness of the CMP pad 130 measured in real time and surface roughness of the CMP pad 130 measured off-line in advance.

The CPU 340 may control the amount of polishing of the wafer W by controlling, through an interface unit 310, pressure applied to the CMP pad 130. The CPU 340 may adjust the amount of polishing of the wafer W by adjusting, according to surface roughness of the CMP pad 130, the pressure applied to the CMP pad 130 in direction E by the carrier central axis 140S, with reference to FIGS. 2 and 3.

Through the interface unit 310, the CPU 340 may adjust pressure applied to the CMP pad conditioner 180 to adjust a conditioning state of the CMP pad 130. The CPU 340 may adjust the conditioning state of the CMP pad 130 by adjusting, according to surface roughness of the CMP pad 130. the pressure applied to the CMP pad 130 in direction C by the conditioner central axis 180S, with reference to FIGS. 2 and 3.

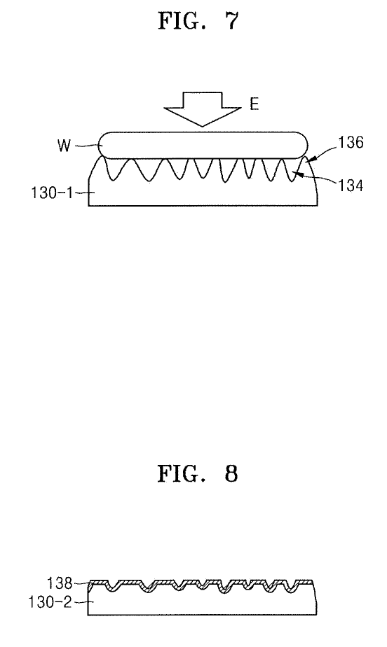

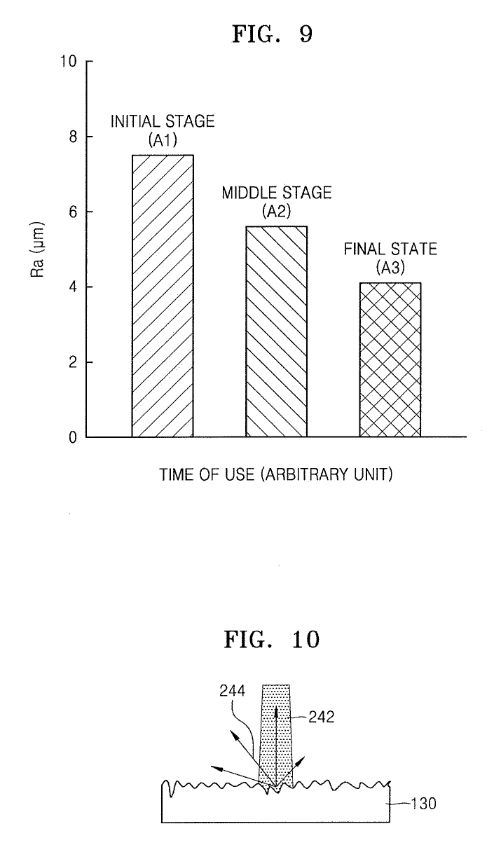

FIGS. 7 and 8 are cross-sectional views for explaining a surface state of a CMP pad of a CMP device and FIG. 9 is a graph of surface roughness of a CMP pad of a CMP device relative time of use, according to an embodiment.

FIG. 7 shows an initial state of the CMP pad. FIG. 8 shows a final state of the CMP pad. Referring to FIG. 9, surface roughness of the CMP pad decreases as the time of use of the CMP pad proceeds through an initial stage a1, a middle stage a2, and a final state a3. An appropriate value may be set when the surface roughness of the CMP pad is in the middle stage a2.

Referring to FIG. 7, a surface of a CMP pad 130-1 may include a recessed portion 134 and a projecting portion 136. The wafer W is placed on the CMP pad 130-1 and the wafer W may be polished in direction E due to pressure applied to the carrier central axis 1405 (refer to e.g. FIGS. 1 to 3).

The recessed portion 134 of the surface of the CMP pad 130-1 may be a path in which the polishing slurry 152 (refer to e.g. FIG. 2) is filled or transferred. A height difference between the recessed portion 134 and the projecting portion 136 of the surface of the CMP pad 130-1 determines surface roughness of the CMP pad 130. Since the surface roughness of the CMP pad 130 is in the initial stage and is greater than the appropriate value, polishing precision of the CMP pad 130 may be improved and reliability of wafer planarization may be improved.

Referring to FIG. 8, a surface of a CMP pad 130-2 is planarized without a distinction between a recessed portion and a projecting portion. Surface roughness of the CMP pad 130-2 of FIG. 8 may be lower than the appropriate value as shown in FIG. 9. Furthermore, the surface of the CMP pad 130-2 of FIG. 8 may be glazed to form a glaze layer. Since the surface roughness of the CMP pad 130-2 is less than the appropriate value, polishing precision of the CMP pad 130-2 may be lowered and reliability of wafer planarization may deteriorate.

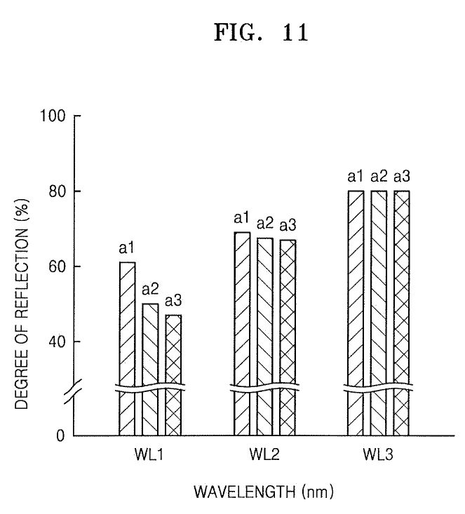

FIGS. 10 and 11 are respectively a diagram and a graph for explaining a method of measuring surface roughness of a CMP pad of a CMP device, according to an example embodiment.

FIGS. 10 and 11 are respectively a diagram and a graph for explaining a method of measuring surface roughness of the CMP pad 130 using the main sensor 222 of the sensor array 220 in the CMP device 400 of FIGS. 1, 5, and 6. The main sensor 222 may be an optical sensor.

Referring to FIG. 10, incident light 242 emitted to a light-emitting area of the main sensor 222 may be incident on the CMP pad 130 and reflected by the CMP pad 130 such that reflected light 244 may be generated. Referring to FIG. 11, a degree of reflection of the reflected light 244 may be different depending on a wavelength of the incident light 242.

Degrees of reflection of the reflected light 244 may vary depending on wavelengths of the incident light 242, e.g., WL1 (400 nm band), WL2 (500 nm band), and WL3 (600 nm) band. As shown in FIG. 11, variation in the degrees at which the reflected light 244 is reflected is increased in the wavelength WL1 relative to the wavelength WL2 or WL3 as time of use of the CMP pad proceeds through the initial stage a1, the middle stage a2, and the final state a3.

Accordingly, when surface roughness of the CMP pad 130 is measured using the main sensor 222 of the sensor array 220 in the CMP device 400 of FIGS. 1, 5 and 6, a specific wavelength of the incident light 242, e.g., the wavelength WL1, may be selected to accurately measure the surface roughness of the CMP pad 130.

Surface roughness of the CMP pad 130 may be precisely measured when a wavelength of the incident light 242 is controlled by the controller 300 (of FIGS. 5 and 6).

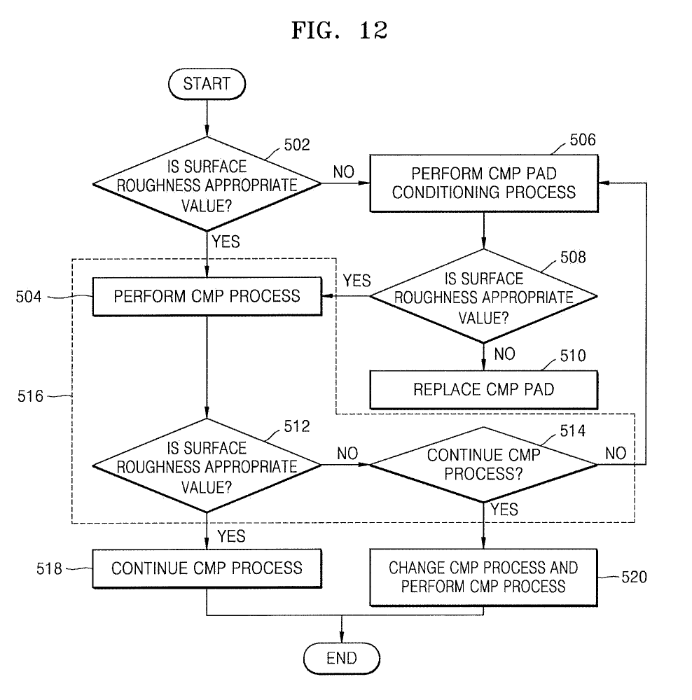

FIG. 12 is a flowchart of a CMP method of a CMP device according to an example embodiment.

In FIG. 12, the explanation of the CMP method is based on the CMP device 400 of FIGS. 1, 5, and 6. The CMP method shown in FIG. 12 is merely an example and may be variously modifie [symbol] operation 502, the CMP method determines whether surface roughness of the CMP pad 130 is of an appropriate value by performing a primary measurement of the surface roughness of the CMP pad 130 before performing a CMP process. Surface roughness of the CMP pad 130 may be measured using the surface-roughness measuring device 200 as described

above. In operation 504, when the primary measurement of the surface roughness of the CMP 130 is of an appropriate value, the CMP process is performed. In operation 506, when the measurement of the surface roughness of the CMP pad 130 is not of an appropriate value, a CMP pad conditioning process for polishing a surface of the CMP pad 130 using the CMP pad conditioner 180 is performed.

In operation 508, the CMP method determines whether surface roughness of the CMP pad 130 is an appropriate value by performing a secondary measurement of the surface roughness of the CMP pad 130 after performing the CMP pad conditioning process. In operation 504, when the secondary measurement of the surface roughness of the CMP pad 130 is of an appropriate value, the CMP process is performed. In operation 510, when the secondary measurement of the surface roughness of the CMP pad 130 is not of an appropriate value, the CMP [symbol] the CMP method determines whether the surface roughness of the CMP pad 130 is of an appropriate value by performing a tertiary measurement of the surface roughness of the CMP pad 130 in real time while performing the CMP process simultaneously. In operation 518, when the tertiary measurement of the surface roughness of the CMP pad 130 is of an appropriate value, the CMP process is continued.

In operation 514, when the tertiary measurement of the surface roughness of the CMP pad 130 is not of an appropriate value, the CMP method determines whether to continue the CMP process. In operation 520, when the CMP process is continued, the CMP process is performed after conditions of the CMP process are changed.

The conditions of the CMP process may include pressure applied to the CMP pad 130 by the carrier central axis 140S, the amount of a polishing slurry, composition of the polishing slurry, and the like. If the CMP process is not continued, the CMP pad conditioning operation (operation 506) may be repeated.

As shown by operation 516, the CMP method may perform operation 504 of performing the CMP process, operation 512 of measuring surface roughness, and operation 514 of determining whether to continue the CMP process in real time.

In an embodiment, the CMP method may perform the CMP process (operation 518) changing process conditions by performing operation 504 of performing the CMP process and operation 512 of measuring surface roughness in real time.

The CMP method may selectively perform operation 518 of performing the CMP process and operation 520 of changing conditions of the CMP process and performing the CMP process.

A CMP device according to embodiments may include a surface-roughness measuring device capable of measuring surface roughness of a CMP pad. Accordingly, the CMP device of may improve reliability of wafer planarization by improving polishing precision by the surface-roughness measuring device.

The CMP device according to embodiments may perform a CMP process by processing surface roughness of the CMP pad measured by the surface-roughness measuring device in real time in a controller and by adjusting a process condition, for example, pressure applied to the CMP pad. Thus, the CMP device may improve reliability of wafer planarization by improving polishing precision.

The CMP device according to embodiments may process surface roughness of the CMP pad, measured by the surface-roughness measuring device in real time, in the controller, and adjust conditioning conditions of a CMP pad conditioner. Therefore, the CMP device may improve polishing efficiency of the CPM pad.

The methods and processes described herein may be performed by code or instructions to be executed by a computer, processor, manager, or controller. Because the algorithms that form the basis of the methods (or operations of the computer, processor, or controller) are described in detail, the code or instructions for implementing the operations of the method embodiments may transform the computer, processor, or controller into a special-purpose processor for performing the methods described herein.

Also, another embodiment may include a computer-readable medium, e.g., a non-transitory computer-readable medium, for storing the code or instructions described above. The computer-readable medium may be a volatile or non-volatile memory or other storage device, which may be removably or fixedly coupled to the computer, processor, or controller which is to execute the code or instructions for performing the method embodiments described herein.

Embodiments are described, and illustrated in the drawings, in terms of functional blocks, units and/or modules. Those skilled in the art will appreciate that these blocks, units and/or modules are physically implemented by electronic (or optical) circuits such as logic circuits, discrete components, microprocessors, hard-wired circuits, memory elements, wiring connections, and the like, which may be formed using semiconductor-based fabrication techniques or other manufacturing technologies. In the case of the blocks, units and/or modules being implemented by microprocessors or similar, they may be programmed using software (e.g., microcode) to perform various functions discussed herein and may optionally be driven by firmware and/or software. Alternatively, each block, unit and/or module may be implemented by dedicated hardware, or as a combination of dedicated hardware to perform some functions and a processor (e.g., one or more programmed microprocessors and associated circuitry) to perform other functions. Also, each block, unit and/or module of the embodiments may be physically separated into two or more interacting and discrete blocks, units and/or modules without departing from the scope of the disclosure. Further, the blocks, units and/or modules of the embodiments may be physically combined into more complex blocks, units and/or modules without departing from the scope of the disclosure.

While embodiments have been particularly shown and described with reference to example embodiments thereof, it will be understood that various changes in form and details may be made therein without departing from the spirit and scope of the following claims.

What is claimed is:

1. A chemical mechanical polishing (CMP) device, comprising:
a rotatable CMP pad on a polishing platen;
a rotatable wafer carrier on an upper portion of the rotatable CMP pad to receive a wafer; and
a surface-roughness measuring device which is located apart from a surface of the rotatable CMP pad in a vertical direction to measure a surface roughness of the rotatable CMP pad,
wherein the surface-roughness measuring device includes a sensor array having a plurality of sensors, the sensor array being horizontally movable over the upper portion of the CMP pad.

2. The CMP device as claimed in claim 1, wherein the plurality of sensors in the sensor array include a main sensor to measure the surface roughness of the rotatable CMP pad and an auxiliary sensor to assist the main sensor and to improve accuracy of the surface roughness measurement of the rotatable CMP pad.

3. The CMP device as claimed in claim 2, wherein the main sensor includes an optical sensor, and the auxiliary sensor includes a temperature sensor and an acoustic sensor.

4. The CMP device as claimed in claim 1, wherein the plurality of sensors in the sensor array are non-contact sensors that are not in contact with the rotatable CMP pad.

5. The CMP device as claimed in claim 1, wherein the surface-roughness measuring device includes a vertical support and a horizontal support on the vertical support, and the sensor array is at one end of the horizontal support and is movable in a horizontal direction by a motor.

6. The CMP device as claimed in claim 1, wherein the rotatable CMP pad is rotatable by a platen central axis, and the sensor array to measure the surface roughness of an entirety of the surface of the rotatable CMP pad.

7. The CMP device as claimed in claim 1, wherein the rotatable wafer carrier is rotatable by a carrier central axis.

8. The CMP device as claimed in claim 1, further comprising a CMP pad conditioner on the upper portion of the rotatable CMP pad.

9. The CMP device as claimed in claim 8, wherein the CMP pad conditioner is rotatable by a conditioner central axis.

10. A chemical mechanical polishing (CMP) device, comprising:
a rotatable CMP pad on a polishing platen;
a rotatable wafer carrier to receive a wafer, the wafer to be in contact with the rotatable CMP pad;
a surface-roughness measuring device which is located apart from a surface of the rotatable CMP pad in a vertical direction to measure a surface roughness of the rotatable CMP pad; and
a controller to control the rotatable wafer carrier and the surface-roughness measuring device,
wherein the surface-roughness measuring device includes a sensor array having a plurality of sensors. the sensor array being horizontally movable over an upper portion of the rotatable CMP pad, and
wherein the controller is to control polishing conditions of the wafer on the rotatable wafer carrier in real time according to the surface roughness of the rotatable CMP pad measured by the surface-roughness measuring device.

11. The CMP device as claimed in claim 10, wherein the sensor array includes a main sensor including an optical sensor and a plurality of auxiliary sensors, the auxiliary sensors including a temperature sensor and an acoustic sensor.

12. The CMP device as claimed in claim 10, wherein the controller includes a signal receiver to receive electrical signals output from the sensor array based on surface roughness or a change in surface roughness of the rotatable CMP pad, and a signal processor to analyze and process the electrical signals received by the signal receiver.

13. The CMP device as claimed in claim 12, wherein the signal processor is connected to a central processing unit (CPU), the CPU to control, through an interface unit, pressure applied to the rotatable CMP pad.

14. The CMP device as claimed in claim 10, further comprising a CMP pad conditioner on the upper portion of the rotatable CMP pad to polish the rotatable CMP pad, the controller to adjust process conditions of the CMP pad conditioner according to the surface roughness measured by the surface-roughness measuring device.

15. The CMP device as claimed in claim 14, wherein:
the controller includes a signal processor to analyze and process electrical signals output from the sensor array based on surface roughness or a change in surface roughness of the rotatable CMP pad, and
the signal processor is connected to a central processing unit (CPU), the CPU to adjust a conditioning state of the rotatable CMP pad by adjusting, through an interface unit, pressure applied to the CMP pad conditioner.
